(19) United States
(12) Patent Application Publication
(10) Pub. No.: US 2002/0142629 A1
(43) Pub. Date: Oct. 3, 2002

(54) Board mounted electrical connector assembly

(76) Inventors: Victor Zaderej, St. Charles, IL (US); Kent E. Regnier, Lombard, IL (US); David E. Dunham, Aurora, IL (US); Kevin Alberts, Naperville, IL (US); David Brearly JR., Naperville, IL (US)

Correspondence Address: MOLEX INCORPORATED, 2222 WELLINGTON COURT, LISLE, IL, 60532, US

(21) Appl. No.: 09/818,797

(22) Filed: Mar. 27, 2001

(51) Int. Cl. H05K 1/00

(52) U.S. Cl. 439/74

(57) ABSTRACT

An electrical connector is provided for mounting on a surface of a printed circuit board having a plurality of holes. The connector includes a dielectric housing having a plurality of terminal-receiving passages. A plurality of first conductive terminals are mounted in some of the passages and include first tail portions insertable in an insertion direction into the holes in the printed circuit board with an interference fit. A plurality of second conductive terminals are mounted in other of the passages and include second tail portions engageable with the surface of the printed circuit board. The second tail portions are constructed to exert forces on the connector in a direction opposite the insertion direction away from the printed circuit board.

### FIELD OF THE INVENTION

This invention generally relates to the art of electrical connectors and, particularly, to an electrical connector for mounting on a printed circuit board with at least some of the terminals insertable into holes in the board.

### BACKGROUND OF THE INVENTION

There are a wide variety of electrical connectors which are designed for mounting on a printed circuit board. Such board mounted connectors have dielectric housings which mount a plurality of terminals which may be both signal terminals or ground terminals. Typically, the terminals have tail portions which are electrically engaged with conductive circuits on the printed circuit board, such as signal circuit traces and ground circuit traces. In some connectors, the tail portions of the signal and/or ground terminals are inserted into holes in the printed circuit board for connection, as by soldering, to circuit traces on the board and/or in the holes. In other connectors, the tail portions are not inserted into holes in the board and, instead, the terminals surface engage circuit traces on the surface of the printed circuit board and are then soldered thereto.

Still further, some connectors are provided with terminals having tail portions insertable into holes in the printed circuit board, wherein the tail portions are “compliant” or at least have compliant sections engageable within the holes. In other words, the compliant tail portions or sections are slightly larger in cross-dimensions than the diameters of the holes. Therefore, when the tail portions are inserted into the holes, they yield slightly to establish an interference fit with the insides of the holes due to the compliancy of the tail portions. Such compliant terminal tails are used to establish good positive contacts when the holes are plated through with the conductive circuit trace material of the printed circuit board. Such compliant tails also may be used to at least in part secure or hold the connector to the board.

Problems often are encountered when using compliant terminal tails or tail portions as described above. These problems often are magnified with the ever-increasing terminal density of board mounted electrical connectors. Specifically, with a high speed connector having a large number of terminals with tail portions inserted into plated through holes in a printed circuit board, the plated through hole can dramatically effect the electrical signal capacitance and inductance. This effect on the electrical signal is related only to the signal terminals and not their corresponding ground terminals. The present invention is directed to solving these problems by providing a unique system wherein a board mounted connector has some terminals with complaint tail portions, mainly the ground or reference terminals, but other terminals, mainly signal terminals, designed to have surface attachment to minimize electrical discontinuities.

### SUMMARY OF THE INVENTION

An object, therefore, of the invention is to provide a new and improved electrical connector for mounting on a surface of a printed circuit board having a plurality of holes.

In the exemplary embodiment of the invention, the connector includes a dielectric housing having a plurality of terminal-receiving passages. A plurality of first conductive terminals are mounted in some of the passages and include first tail portions insertable in an insertion direction into the holes in the printed circuit board with an interference fit. A plurality of second conductive terminals are mounted in other of the passages and include second tail portions engageable with the surface of the printed circuit board. The second tail portions are constructed to exert forces on the connector in a direction opposite the insertion direction away from the printed circuit board, thereby eliminating the need to solder the surface mount terminals to the printed circuit board. This results in a connector having simplified installation to and withdrawal from a substrate as compared to connectors requiring solder to ensure contact of the terminals to the circuit traces.

As disclosed herein, the first tail portions of the first terminals comprise compliant tails. Specifically, the first tail portions comprise eyelet portions of the first terminals engageable within the holes in the printed circuit board with an interference fit.

The invention is shown herein in a connector assembly which includes a pair of mating connectors, with both connectors mountable on printed circuit boards which are generally parallel to each other. The second tail portions of the second terminals of one of the connectors are formed by bowed spring portions of the second terminals. The bowed spring portions define convex surfaces engageable with the surface of one of the printed circuit boards. Each bowed spring portion of each second terminal includes opposite ends. One opposite end is fixed to the respective second terminal and the other opposite end is free to move as the bowed spring portion yields in response to engagement with the surface of the one printed circuit board.

The second tail portions of the second terminals of the other mating connector include spring sections which extend oblique to the insertion direction. The spring sections extend at angles of approximately 30° to the insertion direction. The invention contemplates that the spring sections extend at angles of between 15° and 75° to the insertion direction.

Other objects, features and advantages of the invention will be apparent from the following detailed description taken in connection with the accompanying drawings.

### BRIEF DESCRIPTION OF THE DRAWINGS

The features of this invention which are believed to be novel are set forth with particularity in the appended claims. The invention, together with its objects and the advantages thereof, may be best understood by reference to the following description taken in conjunction with the accompanying drawings, in which like reference numerals identify like elements in the figures and in which:

FIG. 1 is a perspective view of an electrical connector assembly embodying the concepts of the invention;

FIG. 2 is a perspective view looking at the bottom of the connector assembly as viewed in FIG. 1;

FIG. 3 is a perspective view of one of the plug connector modules of the assembly;

FIG. 4 is a perspective view of one of the receptacle connector modules of the assembly;

FIG. 5 is a section taken generally along line 5-5 in FIG. 1;

FIG. 6 is a perspective view of one of the ground terminals of the plug connector module shown in FIG. 3;

FIG. 7 is a perspective view of one of the signal terminals of the plug connector module;

FIG. 8 is an elevational view of the signal terminal of FIG. 7;

FIG. 9 is a perspective view of one of the ground terminals of the receptacle connector modules; and

FIG. 10 is a side elevational view of one of the signal terminals of the receptacle connector module.

### DETAILED DESCRIPTION OF THE PREFERRED EMBODIMENT

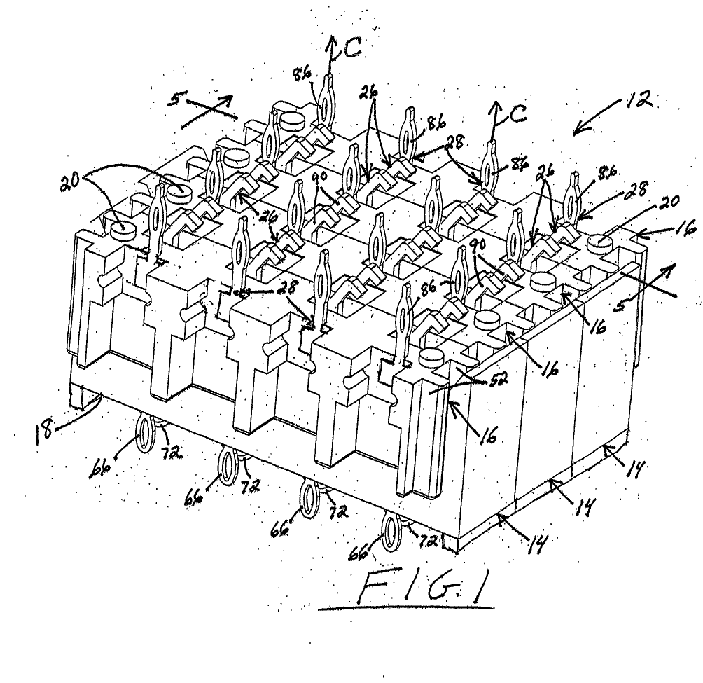

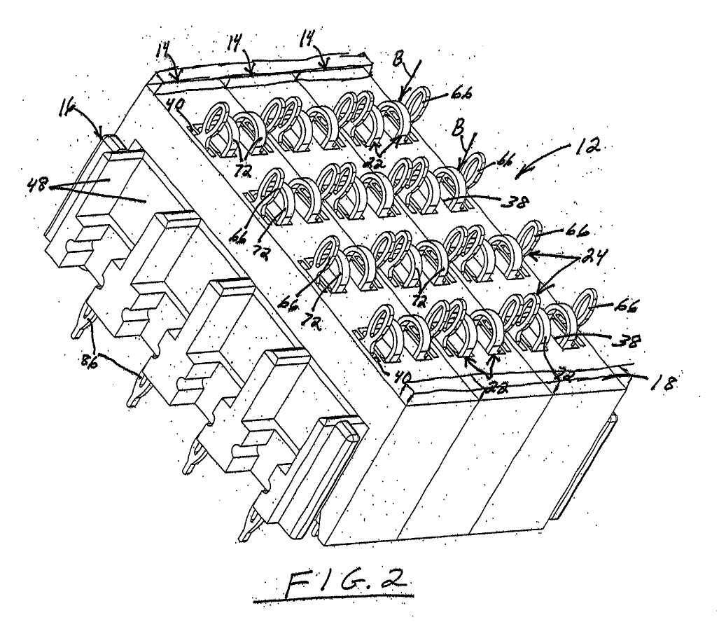

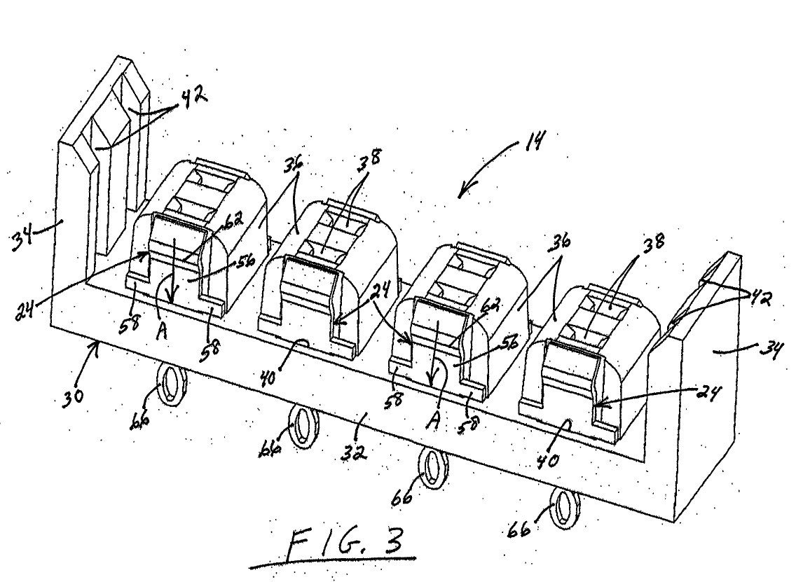

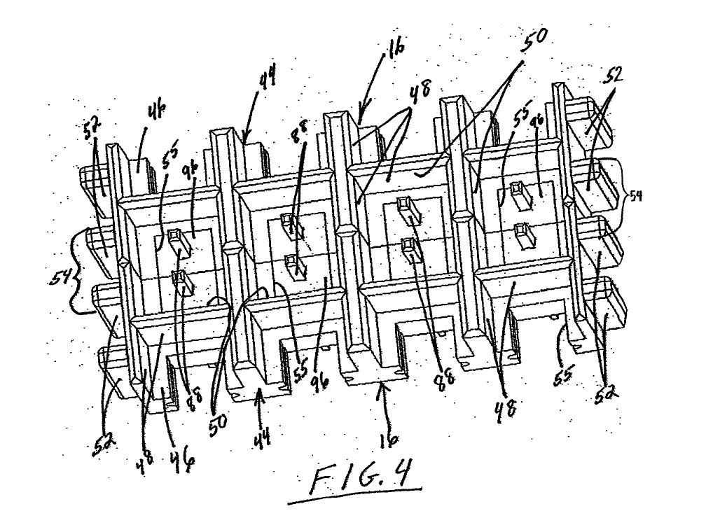

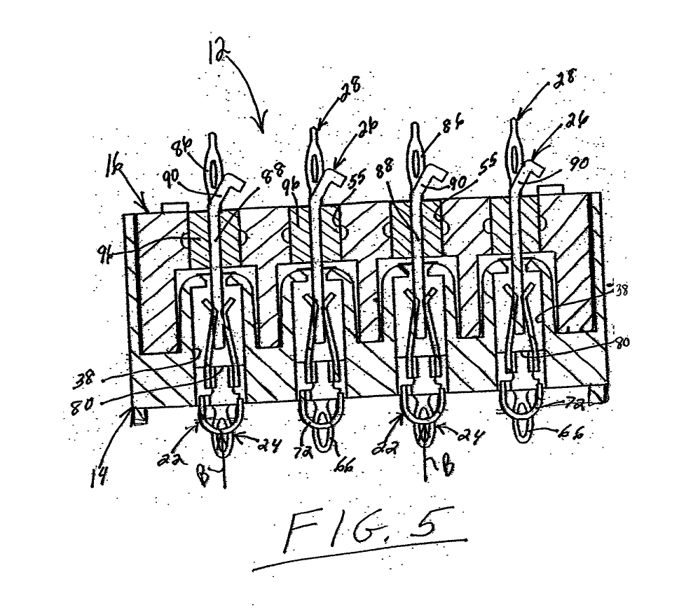

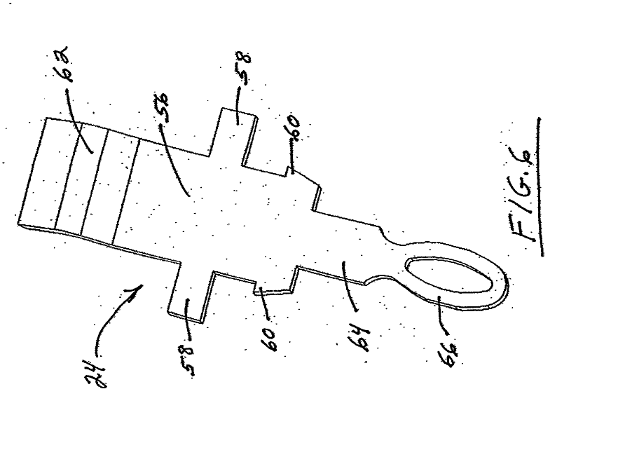

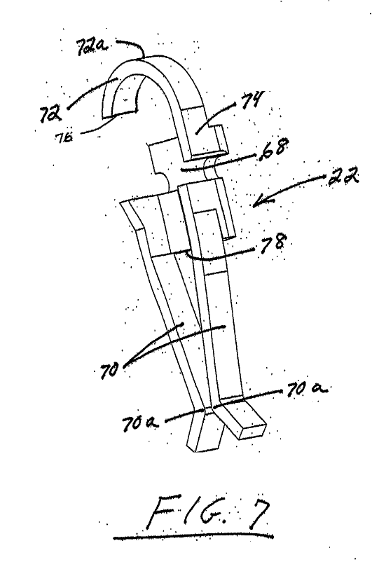

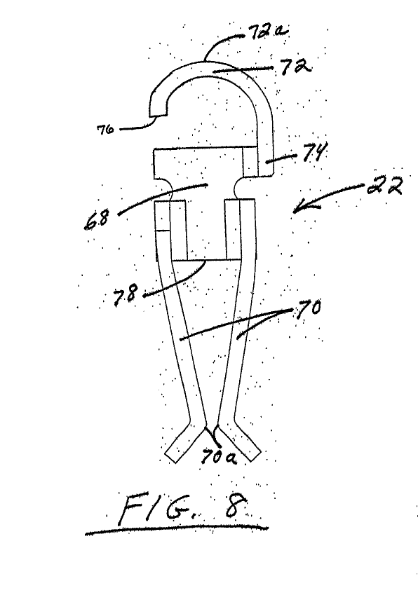

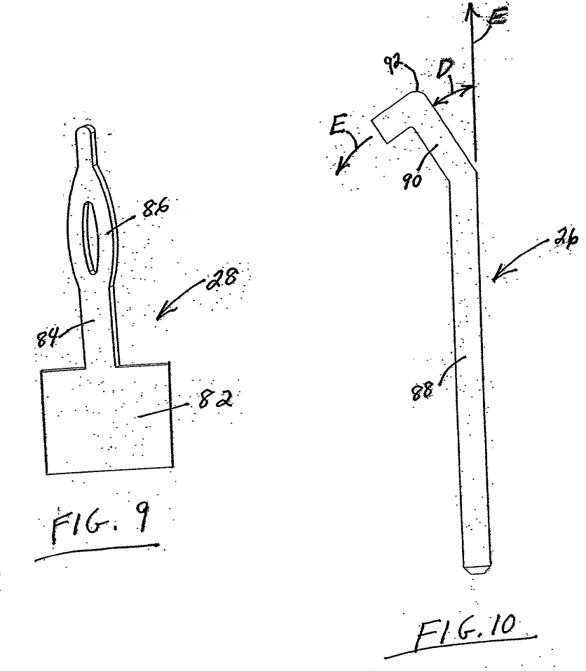

Referring to the drawings in greater detail, and first to FIGS. 1 and 2, the invention is shown herein as embodied in an electrical connector assembly, generally designated 12, which includes a plurality of first connector modules, generally designated 14, which mate with a plurality of second connector modules, generally designated 16. As seen in FIGS. 1 and 2, three first connector modules 14 matingly interengage with four second connector modules 16. As will described and understood more fully hereinafter, first connectors modules 14 will be called plug connector modules or plug modules, and second connector modules 16 will be called receptacle connector modules or receptacle modules, because the plug connector modules have plug portions insertable into receptacles defined by the receptacle connector modules. Plug connector modules 14 combine to define a composite board-mounting face 18 for mounting the plug connector modules on a surface of a first printed circuit board. Receptacle connector modules 16 have a plurality of standoffs 20 (FIG. 1) which combine to define a composite board-mounting face for mounting the receptacle connector modules on a surface of a second printed circuit board in parallel relation with the first printed circuit board. Plug connector modules 14 mount a plurality of signal terminals, generally designated 22, and a plurality of ground terminals, generally designated 24, which have tail portions projecting from board mounting face 18 as seen in FIG. 2. Receptacle connector modules 16 have a plurality of signal terminals, generally designated 26, and a plurality of ground terminals, generally designated 28, which have tail portions projecting from board-mounting face 20 as seen in FIG. 1.

Referring to FIG. 3 particularly in conjunction with FIG. 2, each plug module 14 includes a one-piece housing, generally designated 30, which may be molded of dielectric material such as plastic or the like. The housing has an elongated base 32 with upstanding arms 34 at opposite ends thereof. A plurality of plug portions 36 project upwardly from base 32 and are spaced equidistant longitudinally of the base between arms 34. Each plug 36 has a pair of terminal-receiving passages 38 for receiving a pair of signal terminals described hereinafter. A pair of terminal-receiving passages 40 are formed through base 32 at opposite sides of each plug 36 for receiving a pair of ground terminals 24 for each plug. Finally, a pair of grooves 42 are formed in the inside faces of arms 34 at opposite ends of base 32.

Referring to FIG. 4 particularly in conjunction with FIG. 1, a pair of receptacle modules 16 are shown side-by-side in FIG. 4 for illustration purposes. Each receptacle module 16 includes a one-piece housing, generally designated 44, which may be unitarily molded of dielectric such as plastic or the like. Each housing includes a base 46 having a plurality of upstanding cross walls 48. As clearly seen in FIG. 4, when two receptacle modules 16 are juxtaposed in a side-by-side relationship, the cross walls 48 of the two modules combine to define rectangular receptacles 50 which receive plugs 36 (FIG. 3) of plug modules 14. Actually, each module forms one-half of each receptacle 50. A plurality of tongues or ribs 52 project outwardly from opposite ends of the receptacle modules. Tongues 52 are designed for sliding into grooves 42 (FIG. 3) of plug modules 14. However, as best seen in FIG. 1, it can be seen that plug modules 14 are “staggered” relative to receptacle modules 16 in the assembly of connector assembly 12. Therefore, each pair of grooves 42 of each plug module receives one rib 52 from each one of a pair of adjacent receptacle modules 16 as indicated by brackets 54 at opposite ends of FIG. 4. The interengaging tongue-and-groove arrangement is effective to hold all of the plug and receptacle modules together in a direction generally parallel to the printed circuit boards between which connector assembly 12 is mounted. Receptacle modules 16 also combine to form a plurality of sockets 55 for purposes described hereinafter. Finally, each housing 44 is preferably entirely plated with conductive metal material, and the housing 44 is electrically connected to the printed circuit board by means of terminals 28.

Before proceeding with other assembly features of connector assembly 12, reference is made to FIG. 6 in conjunction with FIG. 3, wherein one of the ground terminals 24 of plug modules 14 is shown. Each ground terminal 24 is stamped and formed of conductive sheet metal material and includes a body 56 having a pair of outwardly projecting wings 58 and a pair of outwardly projecting barbs 60. An outwardly bowed section 62 is formed at one end of the ground terminal, and a tail portion 64 projects from the opposite end of the terminal and terminates in a compliant section 66 in the form of an eyelet.

Referring to plug module 14 in FIG. 3, each ground terminal 24 is inserted into a respective one of the terminal-receiving passages 40 in base 32 of housing 30 in the direction of arrows “A”. When fully inserted, as shown, wings 58 abut against base 32 to form a stop-limit means. Although not visible in the drawing, barbs 60 (FIG. 6) bite into the plastic material of the base within passages 40. Outwardly bowed sections 62 of the ground terminals project outwardly from opposite sides of plugs 36 for positive engagement with the insides of cross walls 48 of receptacles 50 of receptacle modules 16. As stated above, the entire housings 46 of receptacle modules 16 can be plated with conductive material to ground the housings to the respective printed circuit board. Therefore, outwardly bowed sections 62 of ground terminals 24 are commoned through receptacle modules 16 to the printed circuit board to which the receptacle modules are mounted. Compliant sections 66 are sized for insertion into holes in the printed circuit board to which plug module 14 is mounted, with an interference fit. In other words, the eyelets which form compliant sections 66 are slightly larger than the diameters of the holes, so that the eyelets yield and establish an interference fit within the holes in the board.

One of the signal terminals 22 of plug modules 14 is shown in FIGS. 7 and 8. Each signal terminal 22 is stamped and formed of conductive sheet metal material and includes a body 68 having a pair of contact arms 70 projecting from one end thereof. The contact arms have outwardly flared distal ends 70a. A bowed spring portion 72 is formed at the opposite end and defines a convex outside surface 72a. Bowed spring portion 72 has one end 74 which is fixed to body 68 and an opposite free end 76 which is free to move as the bowed spring portion yields in response to engagement with the surface of the printed circuit board to which plug modules 14 are mounted. Finally, body 68 defines a stop shoulder 78 for purposes described below. Signal terminals 22 are inserted into terminal-receiving passages 38 of plug modules 14 in the direction of arrow “B” (FIG. 2). When fully inserted, stop shoulders 78 of the signal terminals engage stop shoulders 80 (FIG. 5) molded integrally within terminal-receiving passages 38.

In operation, when one of the plug modules 14 is mounted to the surface of its respective printed circuit board, compliant sections 66 are inserted into the holes in the printed circuit board with an interference fit, as described above, to provide a positive contact with the board within the holes. At the same time, convex surfaces 72a engage the surface of the board whereby bowed spring portions 72 of signal terminals 22 are flexed inwardly which, in essence, establishes a spring load or stored energy within the bowed spring portions.

FIG. 9 shows one of the ground terminals 28 of receptacle modules 16. Each ground terminal includes a body 82 and a compliant tail portion 84 having an eyelet section 86 for insertion into a respective one of the holes in the printed circuit board to which the receptacle modules are mounted. Like eyelets 66 of ground terminals 24, eyelets 86 of ground terminals 28 are slightly larger than the holes into which they are inserted, whereby the compliant sections yield and establish an interference fit and good contact within the holes. The ground terminals 28 may be individually inserted into their respective housing terminal receiving cavities or the ground terminals may be overmolded into the housings 46. In either case, the ground terminals are commoned with the conductive plating on the housings.

FIG. 10 shows one of the signal terminals 26 for receptacle modules 16. Each signal terminal includes a pin 88 and an angled spring section 90. FIG. 1 shows how angle sections 90 of signal terminals 26, as well as compliant sections 86 of ground terminals 28, project from the board-mounting face of receptacle modules 16.

In FIG. 1, arrows “C” represent the insertion direction of compliant sections 86 of ground terminals 28 into the holes of the printed circuit board to which receptacle modules 16 are mounted. Going back to FIG. 10, the insertion direction “C” is generally in line with pin portion 88 of signal terminal 26. Double-headed arrow “D” represents the angle between angled spring section 90 and the insertion direction “C” described above. This angle should be such as to exert substantial forces on the connector in a direction opposite the insertion direction away from the printed circuit board when the angled section is bent in the direction of arrow “E”. In other words, when the receptacle module is mounted to the respective printed circuit board, a distal end 92 of angled section 90 engages the board and causes the angled section to act as a spring as it bends relative to pin portion 88. This bending action stores the spring forces in the bent angled sections. The angled sections have proven effective when angle “D” is approximately 30°. However, the invention contemplates that this angle can be in a range of 15°-75° as long as the signal terminal is fabricated to exert a force on the connector opposite the insertion direction of the ground terminals into the holes in the board.

Referring back to FIG. 5, it can be seen that pin portions 88 of signal terminals 26 are inserted between contact arms 70 of signal terminals 22 of plug modules 14 when receptacle modules 16 are mated with the plug modules. FIG. 5 also shows that signal terminals 26 are overmolded in dielectric blocks 96 which are inserted into sockets 55 in the housings of the receptacle modules. The dielectric blocks insulate the signal terminals from the plating material on the housings of the receptacle modules. FIG. 4 shows how dielectric blocks 96 are positioned within sockets 55 to position pin portions 88 of the signal terminals within receptacles 50 of the receptacle modules. The dielectric blocks may be press-fit in sockets 55, adhered within the sockets by adhesives or crush-ribs on the blocks may hold the blocks in the sockets.

It will be understood that the invention may be embodied in other specific forms without departing from the spirit or central characteristics thereof. The present examples and embodiments, therefore, are to be considered in all respects as illustrative and not restrictive, and the invention is not to be limited to the details given herein.

What is claimed is:

1. An electrical connector for mounting on a surface of a printed circuit board having a plurality of holes, comprising:
a dielectric housing having a plurality of terminal-receiving passages;
a plurality of first conductive terminals mounted in some of said passages and including first tail portion insertable in an insertion direction into the holes in the printed circuit board with an interference fit; and
a plurality of second conductive terminals mounted in other of said passages and including second tail portions engageable with the surface of the printed circuit board, the second tail portions being constructed to exert forces on the connector in a direction opposite said insertion direction away from the printed circuit board.

2. The electrical connector of claim 1 wherein said first tail portions of the first terminals comprise a compliant section.

3. The electrical connector of claim 2 wherein said first tail portions comprise eyelet portions of the first terminals engageable within the holes in the printed circuit board with an interference fit.

4. The electrical connector of claim 1 wherein said second tail portions of the second terminals comprise bowed spring portions of the second terminals defining convex surfaces engageable with the surface of the printed circuit board.

5. The electrical connector of claim 4 wherein each bowed spring portion of each second terminal includes opposite ends, one opposite end being fixed to the respective second terminal and the other opposite end being free to move as the bowed spring portion yields in response to engagement with the surface of the printed circuit board.

6. The electrical connector of claim 1 wherein said second tail portions of the second terminals include angled spring sections which extend oblique to said insertion direction for engagement with the surface of the printed circuit board.

7. The electrical connector of claim 6 wherein said spring sections extend at angles of approximately 30° to said insertion direction.

8. The electrical connector of claim 7 wherein said spring sections extend at angles of between 15° and 75° to said insertion direction.

9. An electrical connector for mounting on a surface of a printed circuit board having a plurality of holes, comprising:
a dielectric housing having a plurality of terminal-receiving passages;
a plurality of first conductive terminals mounted in some of said passages and including compliant tails including eyelet portions engageable within the holes in the printed circuit board with an interference fit; and
a plurality of second conductive terminals mounted in other of said passages and including bowed spring portions defining convex surfaces engageable with the surface of the printed circuit board.

10. The electrical connector of claim 9 wherein each bowed spring portion of each second terminal includes opposite ends, one opposite end being fixed to the respective second terminal and the other opposite end being free to move as the bowed spring portion yields in response to engagement with the surface of the printed circuit board.

11. An electrical connector for mounting on a surface of a printed circuit board having a plurality of holes, comprising:
a dielectric housing having a plurality of terminal-receiving passages;
a plurality of first conductive terminals mounted on the housing and including compliant tails insertable in an insertion direction into the holes in the printed circuit board and including eyelet portions engageable within the holes in the printed circuit board with an interference fit; and
a plurality of second conductive terminals mounted on the housing and including angled spring sections which extend oblique to said insertion direction for engagement with the surface of the printed circuit board.

12. The electrical connector of claim 11 wherein said spring sections extend at angles of approximately 30° to said insertion direction.

13. The electrical connector of claim 12 wherein said spring sections extend at angles of between 15° and 75° to said insertion direction.
